(19) United States
(12) Patent Application Publication
(10) Pub. No.: US 2024/0297095 A1
(43) Pub. Date: Sep. 5, 2024

(54) HEAT TRANSPORT DEVICE AND SEMICONDUCTOR MODULE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); Taiyo Wire Cloth Co., Ltd., Osaka-shi (JP); Shikoku Instrumentation CO., LTD., Nakatado-gun (JP); Monatec Co., Ltd., Makinohara-shi (JP)

(72) Inventors: Shinya ITO, Nisshin-shi (JP); Tomohito IWASHIGE, Nisshin-shi (JP); Masayuki KAMIYA, Nisshin-shi (JP); Hiroki YOKOYAMA, Higashiosaka-shi (JP)

(21) Appl. No.: 18/418,559

(22) Filed: Jan. 22, 2024

(30) Foreign Application Priority Data
Mar. 3, 2023 (JP) 2023-032766

(51) Int. Cl. H01L 23/427

(52) U.S. Cl. CPC H01L 23/427

(57) ABSTRACT

A heat transport device includes a housing, a wick, and a vapor passage. The housing has a sealed space in which a working fluid is sealed. The wick forms a capillary passage through which a liquid-phase working fluid flows inside the housing. A gas-phase working fluid flows through the vapor passage inside the housing. An outer wall of the housing has a heating element disposing portion on which a heating element is disposed, and a non-disposing portion on which a heating element is not disposed. An internal portion of the housing has a heat receiving portion overlapping with the heating element disposing portion in a thickness direction of the housing and a heat radiating portion overlapping with the non-disposing portion in the thickness direction. Both the wick and the vapor passage are provided to extend over the heat receiving portion and the heat radiating portion.

### CROSS REFERENCE TO RELATED APPLICATION

This application is based on Japanese Patent Application No. 2023-032766 filed on Mar. 3, 2023, the disclosure of which is incorporated herein by reference.

### TECHNICAL FIELD

The present disclosure relates to a heat transport device and a semiconductor module.

### BACKGROUND

A heat transport device such as a vapor chamber or a heat pipe is used as a heat dissipation device for a heating element such as a semiconductor element that generates heat by energization.

### SUMMARY

According to an aspect of the present disclosure, a heat transport device configured to transport heat generated by a heating element includes: a housing having a sealed space in which a working fluid is sealed; a wick forming a capillary passage through which a liquid-phase working fluid flows inside the housing; and a vapor passage communicating with the wick inside the housing and through which a gas-phase working fluid flows. An outer wall of the housing has a heating element disposing portion on which the heating element is disposed, and a non-disposing portion on which the heating element is not disposed. An internal portion of the housing has a heat receiving portion positioned to correspond to the heating element disposing portion in a thickness direction of the housing, and a heat radiating portion positioned to correspond to the non-disposing portion in the thickness direction. Both the wick and the vapor passage are provided to extend over the heat receiving portion and the heat radiating portion.

### BRIEF DESCRIPTION OF THE DRAWINGS

FIG. 1 is a cross-sectional view illustrating a semiconductor module that includes a heat transport device according to a first embodiment, perpendicular to a thickness direction of a housing.

FIG. 2 is a cross-sectional view taken along line II-II in FIG. 1.

FIG. 3 is a cross-sectional view taken along line III-III in FIG. 1.

FIG. 4 is a cross-sectional view taken along line IV-IV in FIG. 3.

FIG. 5 is an enlarged view of an area V in FIG. 1.

FIG. 6 is an enlarged view illustrating a semiconductor module that includes a heat transport device of a comparative example, corresponding to FIG. 5.

FIG. 7A is a cross-sectional view of an area VII in FIG. 6.

FIG. 7B is a schematic view of FIG. 7A.

FIG. 8A is a cross-sectional view of an area VIII in FIG. 5.

FIG. 8B is a schematic view of FIG. 8A.

FIG. 9 is a graph showing a relationship between a power loss and a thermal resistance in the semiconductor module of the first embodiment, a semiconductor module of a comparative example, and a copper plate.

FIG. 10 is an enlarged view illustrating a semiconductor module that includes a heat transport device according to a second embodiment, corresponding to FIG. 5.

FIG. 11 is an enlarged view illustrating a semiconductor module that includes a heat transport device according to a third embodiment, corresponding to FIG. 5.

FIG. 12 is an enlarged view illustrating a semiconductor module that includes a heat transport device according to a fourth embodiment, corresponding to FIG. 5.

### DETAILED DESCRIPTION

Conventionally, a heat transport device such as a vapor chamber or a heat pipe is known. A heat transport device is used as a heat dissipation device for a heating element such as a semiconductor element that generates heat by energization.

A heat transport device includes a wick through which a liquid-phase working fluid flows, and a vapor passage through which a gas-phase working fluid flows, inside a housing having a sealed space. The wick is referred to as a capillary flow path, and the vapor passage is referred to as a vapor diffusion flow path. A semiconductor element as a heating element is provided on a part of an outer wall of the housing of the heat transport device to constitute a semiconductor module.

In the following description, a portion of the outer wall of the housing on which the heating element is disposed is referred to as a heating element disposing portion, and a portion of the outer wall of the housing excluding the heating element disposing portion is referred to as a heating element non-disposing portion. A portion located inside the housing in the thickness direction of the housing with respect to the heating element disposing portion is referred to as a heat receiving portion, and a portion located inside the housing in the thickness direction of the housing with respect to the heating element non-disposing portion is referred to as a heat radiating portion. In the heat transport device, the wick is provided across the heat radiating portion and the heat receiving portion, and the vapor passage is provided only in the heat radiating portion.

In this heat transport device, when the heating element disposing portion of the housing receives heat from the heating element, the working fluid stored in the wick evaporates in the heat receiving portion, and the working fluid that has become a gas moves to the vapor passage. Then, when the working fluid flows through the vapor passage, the working fluid dissipates heat from the heating element non-disposing portion to the outside air or the like and condenses, and the working fluid that has become a liquid flows through the wick and returns to the heat receiving portion again. By such circulation of the working fluid, the heat transport device can cause the heating element to radiate heat.

The inventors of the present disclosure have found the following issues as a result of intensive studies on the heat transport device. That is, in case where the vapor passage is provided only in the heat radiating portion, the distance from the center of the heat receiving portion to the vapor passage is long. Therefore, when the heating element disposing portion of the housing receives heat from the heating element and the working fluid stored in the wick in the heat receiving portion evaporates, the flow velocity of the working fluid decreases when the gas phase working fluid moves to the vapor passage, and the vapor diffusion function deteriorates. Therefore, the heat transport device has room for improvement in heat transport efficiency.

The present disclosure provides a heat transport device and a semiconductor module capable of efficiently transporting heat generated by a heating element.

According to a first aspect of the present disclosure, a heat transport device configured to transport heat generated by a heating element includes: a housing having a sealed space in which a working fluid is sealed; a wick forming a capillary passage through which a liquid-phase working fluid flows inside the housing; and a vapor passage communicating with the wick inside the housing and through which a gas-phase working fluid flows. An outer wall of the housing has a heating element disposing portion on which the heating element is disposed, and a non-disposing portion on which the heating element is not disposed. An internal portion of the housing has a heat receiving portion positioned to correspond to the heating element disposing portion in a thickness direction of the housing, and a heat radiating portion positioned to correspond to the non-disposing portion in the thickness direction. Both the wick and the vapor passage are provided across the heat receiving portion and the heat radiating portion.

Accordingly, both the wick and the vapor passage are provided in the heat receiving portion inside the housing. Therefore, the distance between the center of a part of the wick provided in the heat receiving portion and the vapor passage is reduced. Since the working fluid evaporated in the wick rapidly flows into the vapor passage, the flow velocity of the working fluid can be kept high. Therefore, in this heat transport device, the vapor diffusion function is improved, and the heat generated by the heating element can be efficiently transported from the heat receiving portion to the heat radiating portion.

According to a second aspect of the present disclosure, a semiconductor module includes a semiconductor element as a heating element that generates heat by energization, and the heat transport device configured to transport the heat generated by the semiconductor element from the heat receiving portion to the heat radiating portion.

In this case, the semiconductor module also has the same effects as those of the first aspect of the present disclosure.

Hereinafter, embodiments of the present disclosure will be described with reference to the drawings. In the following embodiments, portions that are mutually the same or equivalent are denoted by the same reference signs, and the description thereof will be omitted.

### First Embodiment

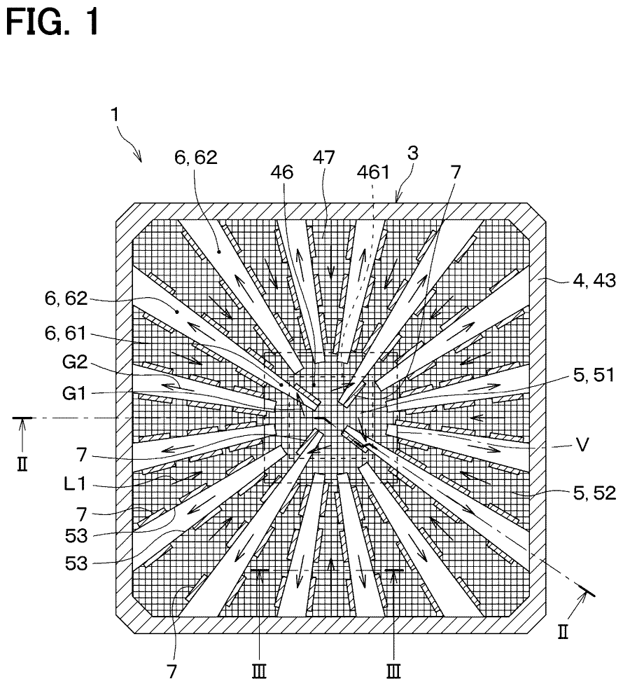

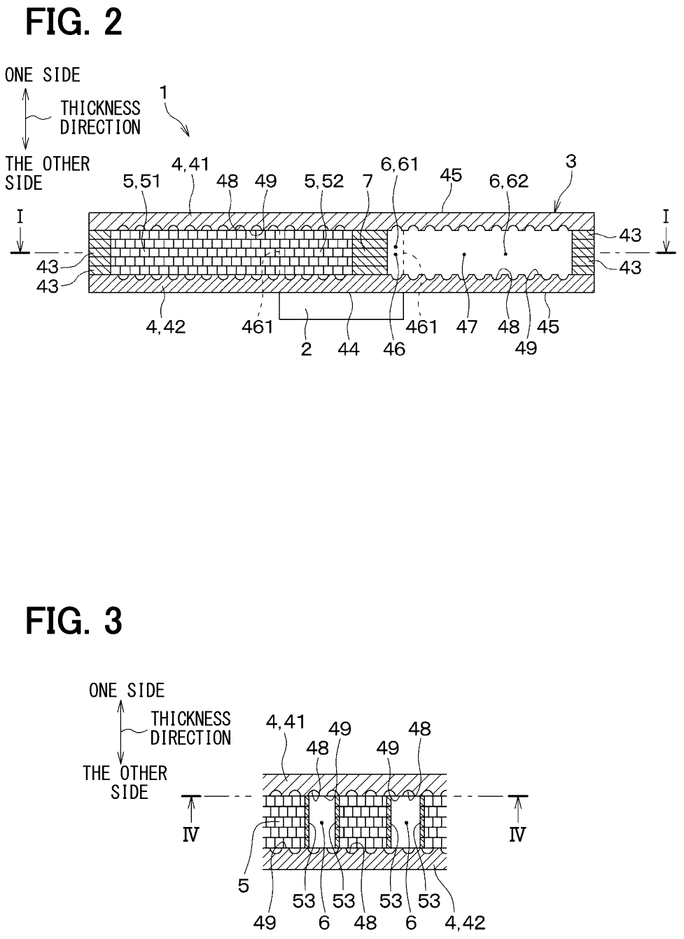

A first embodiment will be described with reference to the drawings. As shown in FIGS. 1 and 2, a semiconductor module 1 of the first embodiment includes a semiconductor element 2 and a heat transport device 3. The semiconductor element 2 is a heating element that generates heat when energized. The heat transport device 3 is a heat dissipation device that transports and dissipates heat generated by the semiconductor element 2. Specifically, the heat transport device 3 is a vapor chamber or a heat pipe.

Hereinafter, the configuration of the heat transport device 3 will be described. As illustrated in FIGS. 1 and 2, the heat transport device 3 includes a housing 4, a wick 5, a vapor passage 6, and a columnar portion 7.

The housing 4 is formed in a flat plate shape, and has a sealed space in which the working fluid is sealed. As the working fluid, for example, pure water having a large latent heat is used. The working fluid is not limited to water, and may be, for example, ethanol, methanol, acetone, or the liked. The working fluid is sealed in the sealed space inside the housing 4 in a decompressed state.

The housing 4 has an upper plate 41 provided on one side in the thickness direction, a lower plate 42 provided on the other side in the thickness direction, and plural intermediate plates 43 provided between the upper plate 41 and the lower plate 42. The upper plate 41, the lower plate 42, and the intermediate plates 43 are formed of a metal material having a high thermal conductivity such as copper. The upper plate 41, the lower plate 42, and the intermediate plates 43 are joined by pressure-bonding. Specifically, the upper plate 41, the intermediate plates 43, and the lower plate 42 are stacked in this order, and are thermocompression-bonded (that is, diffusion-bonded) in a state of being pressurized in the thickness direction. The fact that the upper plate 41, the lower plate 42, and the intermediate plates 43 are pressure-bonded can be seen from the appearance and the cross-sectional view.

The semiconductor element 2 as a heating element is disposed at a substantially central portion of the lower plate 42 of the housing 4. In the following description, a portion of the outer wall of the housing 4 on which the heating element is disposed is referred to as a heating element disposing portion 44, and a portion of the outer wall of the housing 4 excluding the heating element disposing portion 44 is referred to as a non-disposing portion 45. For example, the non-disposing portion 45 may be exposed to the air, or may be connected to a heat sink, a fin, or the like (not illustrated). Further, a portion located inside the housing 4 in the thickness direction of the housing 4 with respect to the heating element disposing portion 44 is referred to as a heat receiving portion 46, and a portion located inside the housing 4 in the thickness direction of the housing 4 with respect to the non-disposing portion 45 is referred to as a heat radiating portion 47. In FIGS. 1, 2, 6 and 10 to 12, the boundary between the heat receiving portion 46 and the heat radiating portion 47 is indicated by a broken line denoted by reference numeral 461.

The wick 5 is defined in the intermediate plates 43 and forms a capillary passage. In each of the intermediate plates 43, a portion constituting the wick 5 is formed in a lattice shape (in other words, a mesh shape). The intermediate plates 43 are stacked such that lattices or meshes thereof are staggered in the thickness direction. The gaps of the lattice or mesh of the wick 5 are sized such that the liquid-phase working fluid flows by capillary force. Therefore, the liquid-phase working fluid flows through the wick 5 by capillary force.

The wick 5 is provided over a part of the heat receiving portion 46 and a part of the heat radiating portion 47 inside the housing 4. In the following description, a part of the wick 5 provided in the heat receiving portion 46 is referred to as a “heat receiving wick 51”, and a part of the wick 5 provided in the heat radiating portion 47 is referred to as a “heat radiating wick 52”. The heat receiving wick 51 has substantially the same outer shape and size as the heat receiving portion 46. The heat radiating wick 52 extends radially from the heat receiving wick 51 toward the outer periphery of the housing 4. The heat receiving wick 51 and the heat radiating wick 52 are formed continuously.

The vapor passage 6 is a space formed between the upper plate 41, the lower plate 42, and the intermediate plates 43. A gas-phase working fluid flows through the vapor passage 6. The vapor passage 6 is provided over a part of the heat receiving portion 46 and a part of the heat radiating portion 47 inside the housing 4. In the following description, a part of the vapor passage 6 provided in the heat receiving portion 46 is referred to as a “heat receiving vapor passage 61”, and a part of the vapor passage 6 provided in the heat radiating portion 47 is referred to as a “heat radiating vapor passage 62”. As shown in FIGS. 1 and 5, the heat receiving vapor passage 61 of the vapor passage 6 is shaped so as to extend from the heat radiating vapor passage 62 into the heat receiving portion 46 across the boundary 461 between the heat receiving portion 46 and the heat radiating portion 47. On the other hand, the heat radiating vapor passage 62 includes a first passage that extends radially from the heat receiving vapor passage 61 toward the outer periphery of the housing 4, and a second passage that extends radially from a position outside the heat receiving portion 46 toward the outer periphery of the housing 4.

As shown in FIG. 3, a partition wall 53 is provided between the vapor passage 6 and the wick 5. The partition wall 53 can reduce the amount of heat exchanged between the gas-phase working fluid flowing through the vapor passage 6 and the liquid-phase working fluid flowing through the wick 5.

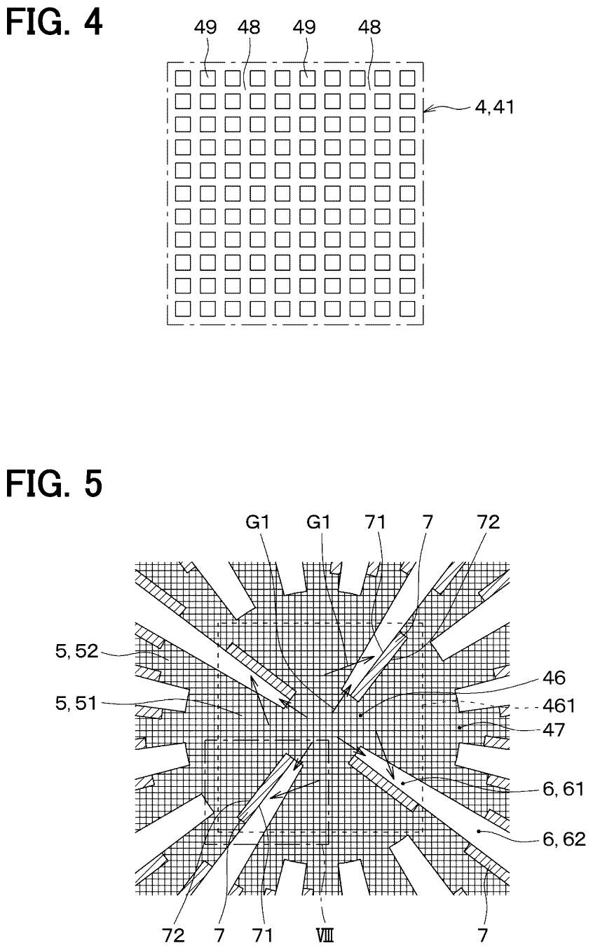

As shown in FIG. 3 and FIG. 4, grooves 48 are provided in each of the inner wall of the upper plate 41 and the inner wall of the lower plate 42. Specifically, each of the inner wall of the upper plate 41 and the inner wall of the lower plate 42 has plural protrusions 49 protruding inward. The protrusions 49 are arranged vertically and horizontally at predetermined intervals. The passage between the protrusions 49 adjacent to each other becomes the groove 48. The width of the groove 48 is set to such a size that the liquid-phase working fluid flows by capillary force. Therefore, the working fluid that has dissipated heat and condensed in the non-disposing portion 45 while flowing through the heat radiating vapor passage 62 flows into the wick 5 via the groove 48. Further, the working fluid evaporated in the heat receiving wick 51 flows into the vapor passage 6 via the groove 48.

As shown in FIGS. 1 and 2, the columnar portion 7 is provided at plural positions in a part of the heat receiving portion 46 and a part of the heat radiating portion 47. The columnar portion 7 is a reinforcing portion that connects one inner wall on the one side and the other inner wall on the other side in the thickness direction of the housing 4. By providing the columnar portion 7 in a part of the heat receiving portion 46, it is possible to restrict the housing 4 from expanding in the thickness direction due to volume expansion or the like caused by evaporation of the working fluid in the heat receiving portion 46. As shown in FIG. 1, the columnar portions 7 may be provided not only in the heat receiving portion 46 but also in the heat radiating portion 47.

As shown in FIGS. 1 and 5, at least a first side 71 of the outer periphery of the columnar portion 7 faces the vapor passage 6. A second side 72 of the outer periphery of the columnar portion 7 that does not face the vapor passage 6 is in contact with the wick 5. The reason will be described below.

As shown in FIG. 2, the columnar portion 7 is formed by pressure-bonding a part of the upper plate 41, a part of the lower plate 42, and a part of the intermediate plate 43 at the time of manufacturing the heat transport device 3. The fact that the columnar portion 7 is formed by pressure-bonding can be confirmed from a cross-sectional view of the heat transport device 3. In manufacturing the heat transport device 3, when the upper plate 41, the lower plate 42, and the intermediate plate 43 are pressure-bonded to each other, the columnar portion 7 may bulge in a direction perpendicular to the thickness direction of the housing 4 from its original shape. In this case, when a part of the wick 5 adjacent to the columnar portion 7 is deformed by being pressed by the columnar portion 7, the capillary force of the deformed part decreases, and the function of allowing the working fluid to flow therethrough may deteriorate.

Therefore, in the first embodiment, at least the first side 71 of the outer periphery of the columnar portion 7 faces the vapor passage 6 without being in contact with the wick 5. Accordingly, even when the columnar portion 7 bulges in the direction perpendicular to the thickness direction of the housing 4 from the original shape at the time of manufacturing the heat transport device 3, the wick 5 is not deformed at a position where the columnar portion 7 faces the vapor passage 6. Therefore, a decrease in the capillary force of the wick 5 is suppressed, and the flow function of the working fluid can be improved.

Next, the operation of the semiconductor module 1 of the first embodiment will be described.

When the semiconductor element 2 is energized, heat is generated in the semiconductor element 2 according to power loss. The heat generated by the semiconductor element 2 is transmitted from the heating element disposing portion 44 of the housing 4 to the heat receiving portion 46, and the liquid-phase working fluid stored in the heat receiving wick 51 evaporates. The working fluid that has become a gas in the heat receiving wick 51 flows into the vapor passage 6 via the groove 48 of the upper plate 41 or the groove 48 of the lower plate 42 as indicated by an arrow G1 in FIG. 5. As indicated by an arrow G2 in FIG. 1, the gas-phase working fluid radiates heat from the non-disposing portion 45 to the outside air or the like and condenses while moving through the vapor passage 6 toward the outer peripheral side of the housing 4. Then, the working fluid that has become liquid flows into the heat radiating wick 52 via the groove 48 of the upper plate 41 or the groove 48 of the lower plate 42, flows through the heat radiating wick 52, and flows back to the heat receiving wick 51 again as indicated by an arrow L1 in FIG. 1. Such circulation of the working fluid allows the heat transport device 3 to dissipate heat from the semiconductor element 2.

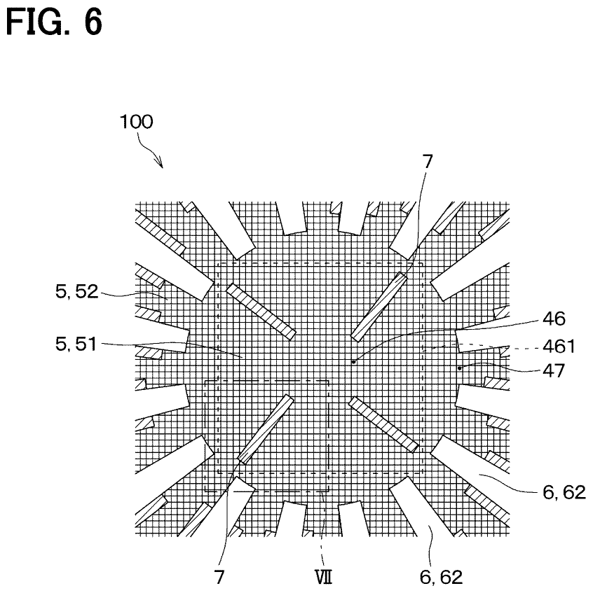

For comparison with the semiconductor module 1 of the first embodiment, a semiconductor module 100 of a comparative example will be described with reference to FIG. 6. FIG. 6 is an enlarged view corresponding to FIG. 5 referred to in the first embodiment in the heat transport device 3 of the semiconductor module 100 of the comparative example.

As illustrated in FIG. 6, in the comparative example, the vapor passage 6 includes only the heat radiating vapor passage 62 and does not include the heat receiving vapor passage 61. Therefore, the distance from the center of the heat receiving portion 46 to the heat radiating vapor passage 62 is long. In this configuration, the flow rate is lowered when the vapor moves to the heat radiating vapor passage 62 and the vapor diffusion function deteriorates, since the heat generated by the semiconductor element 2 is transmitted from the heating element disposing portion 44 to the heat receiving portion 46 and the working fluid stored in the heat receiving wick 51 evaporates.

In the comparative example, the entire outer periphery of the columnar portion 7 provided in the heat receiving portion 46 is in contact with the wick 5. Therefore, if the columnar portion 7 bulges due to the pressure-bonding of the upper plate 41, the lower plate 42, and the intermediate plate 43, a part of the wick 5 adjacent to the columnar portion 7 is deformed at the time of manufacturing the heat transport device 3. In this case, the capillary force of the deformed part is reduced, and the flow-through function of the working fluid is deteriorated.

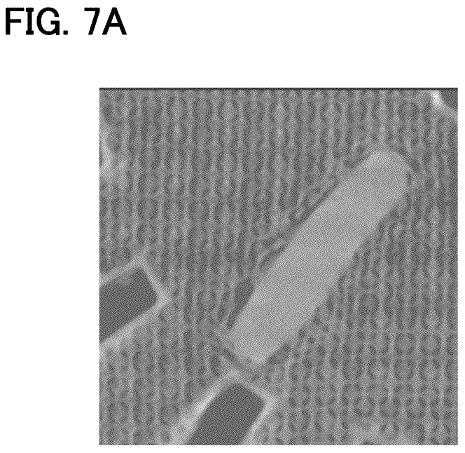

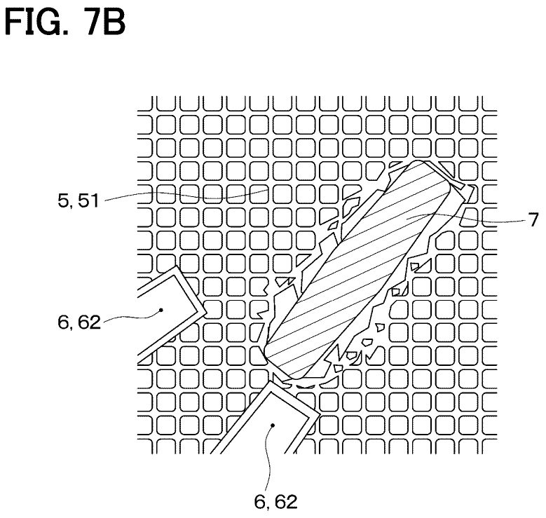

FIG. 7A is a cross-sectional view of an area VII in FIG. 6, and FIG. 7B is a schematic view of FIG. 7A. As illustrated in FIGS. 7A and 7B, in the comparative example, it can be seen that the entire outer periphery of the columnar portion 7 is in contact with the wick 5, and a part of the wick 5 in contact with the outer periphery of the columnar portion 7 is deformed.

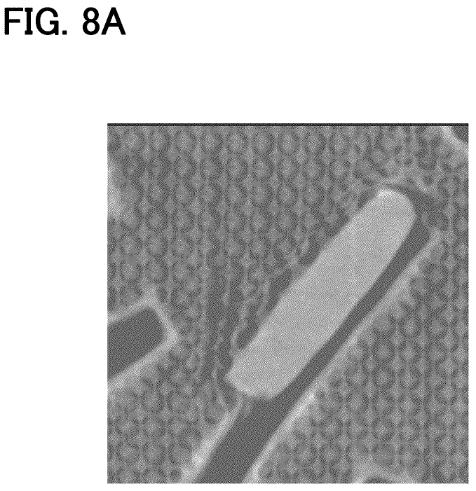

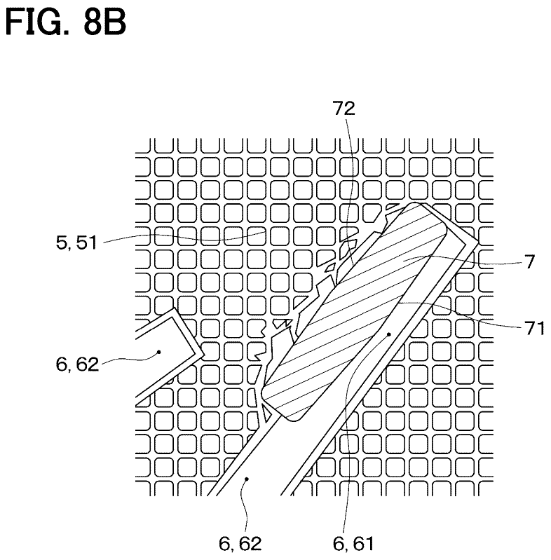

In contrast, FIG. 8A is a cross-sectional view of an area VIII in FIG. 5, and FIG. 8B is a schematic view of FIG. 8A. As shown in FIGS. 8A and 8B, in the first embodiment, the first side 71 of the outer periphery of the columnar portion 7 faces the vapor passage 6. Therefore, the area of the columnar portion 7 in contact with the wick 5 is smaller than that in the configuration of the comparative example. Therefore, the number of the deformed parts of the wick 5 deformed in contact with the outer periphery of the columnar portion 7 is smaller than that in the comparative example. Accordingly, in the first embodiment, it is possible to suppress the deterioration in the flow of the working fluid.

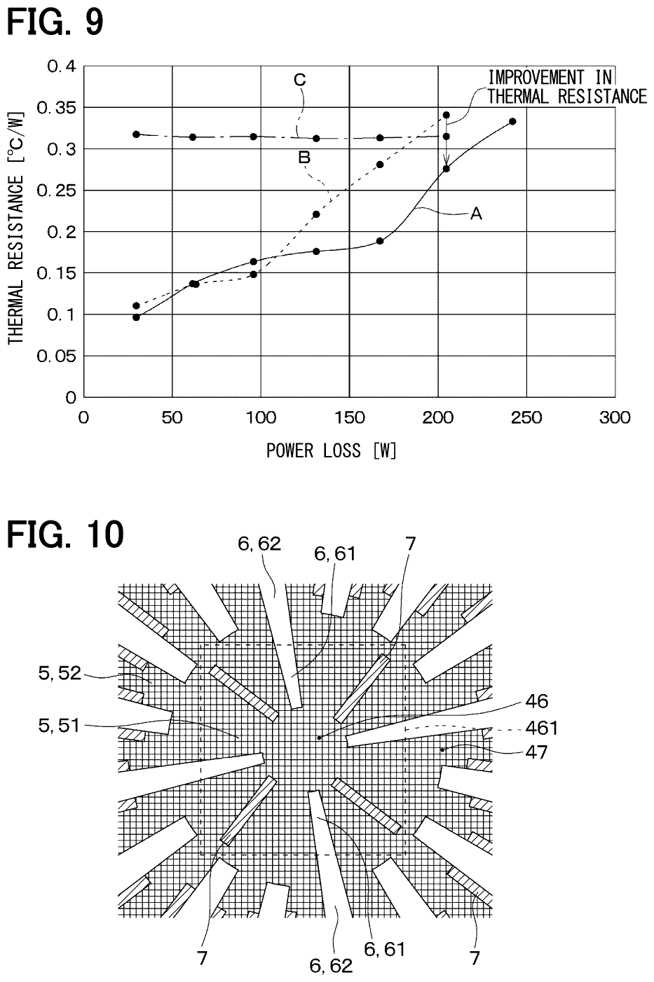

FIG. 9 is a graph showing the results of experiments conducted by the inventors on the semiconductor module 1 according to the first embodiment, the semiconductor module 100 of the comparative example, and a copper plate.

In FIG. 9, the horizontal axis represents the power loss when the semiconductor element 2 is energized, and the vertical axis represents the thermal resistance between an arbitrary position of the heating element disposing portion 44 and an arbitrary position of the non-disposing portion 45 in the housing 4. The power loss on the horizontal axis can be read as the amount of heat received by the heat receiving portion 46.

In FIG. 9, the relationship between the power loss and the thermal resistance in the semiconductor module 1 according to the first embodiment is indicated by a solid line A. A broken line B indicates the relationship between the power loss and the thermal resistance in the semiconductor module 100 of the comparative example. A single chain line C shows the relationship between the power loss and the thermal resistance when the heat transport device 3 of the semiconductor module 1 is a simple copper plate.

As indicated by the broken line B in FIG. 9, in the comparative example, when the power loss is about 100 W or more, the increase rate of the thermal resistance with respect to the power loss increases. In the comparative example, the thermal resistance is larger than that of the copper plate indicated by the single chain line C at a power loss of about 200 W.

As indicated by the solid line A in FIG. 9, in the first embodiment, when the power loss is about 170 W or more, the increase rate of the thermal resistance with respect to the power loss increases. In the first embodiment, when the power loss is about 200 W, the thermal resistance is smaller than that of the comparative example indicated by the broken line B and the copper plate indicated by the single chain line C. Therefore, it can be said that the thermal resistance, at the time of high power loss, is greatly improved in the configuration of the first embodiment as compared with the configuration of the comparative example.

The heat transport device 3 and the semiconductor module 1 of the first embodiment achieve the following effects.

(1) In the heat transport device 3 of the first embodiment, both the heat receiving wick 51 of the wick 5 and the heat receiving vapor passage 61 of the vapor passage 6 are provided in the heat receiving portion 46 inside the housing 4. Therefore, the distance between the center of the heat receiving wick 51 and the vapor passage 6 is reduced, and the working fluid evaporated in the heat receiving wick 51 rapidly flows into the vapor passage 6, so that the flow velocity of the working fluid can be kept as high. Therefore, the vapor diffusion function of the heat transport device 3 is improved, and the heat generated by the semiconductor element 2 can be efficiently radiated.

(2) The heat transport device 3 of the first embodiment includes the columnar portion 7 in a part of the heat receiving portion 46. Therefore, it is possible to restrict the housing 4 from expanding in the thickness direction due to volume expansion or the like caused by evaporation of the working fluid in the heat receiving portion 46. Therefore, the heat resistance of the heat transport device 3 can be improved.

(3) In the first embodiment, the columnar portion 7 is formed by pressure-bonding a part of the upper plate 41, a part of the lower plate 42, and a part of the intermediate plate 43. Accordingly, the columnar portion 7 can be formed inside the housing 4 by pressure-bonding the upper plate 41, the lower plate 42, and the intermediate plate 43.

(4) In the first embodiment, at least the first side 71 of the outer periphery of the columnar portion 7 provided in the heat receiving portion 46 faces the vapor passage 6. Accordingly, even if the columnar portion 7 bulges in the direction perpendicular to the thickness direction of the housing 4 from the original shape due to the pressure bonding of the upper plate 41, the lower plate 42, and the intermediate plate 43 at the time of manufacturing the heat transport device 3, the wick 5 is not deformed at the location where the columnar portion 7 faces the vapor passage 6. Therefore, a decrease in the capillary force of the wick 5 is suppressed, and the flow function of the working fluid can be improved.

(5) In the first embodiment, the second side 72 of the outer periphery of the columnar portion 7 provided in the heat receiving portion 46, which does not face the vapor passage 6, is in contact with the wick 5. Accordingly, heat is easily transferred from the semiconductor element 2 to the heat receiving wick 51 via the columnar portion 7 provided in the heat receiving portion 46. Since the distance between the center of the heat receiving wick 51 and the vapor passage 6 is short, the working fluid evaporated in the heat receiving wick 51 by the heat quickly flows into the vapor passage 6. Therefore, the heat transport device 3 can improve the vapor diffusion function.

(6) The semiconductor module 1 of the first embodiment includes the semiconductor element 2 and the heat transport device 3 configured to transport heat generated by the semiconductor element 2 from the heat receiving portion 46 to the heat radiating portion 47. The heat transport device 3 has the above-described configuration. Therefore, the semiconductor module 1 can also efficiently dissipate heat generated by the semiconductor element 2.

### Second Embodiment

A second embodiment will be described. In the second embodiment, a part of the configuration of the heat transport device 3 is changed from that of the first embodiment, and the other parts are the same as those of the first embodiment. Therefore, only parts different from those of the first embodiment will be described.

As shown in FIG. 10, in the second embodiment, the vapor passage 6 is provided to extend over a part of the heat receiving portion 46 and a part of the heat radiating portion 47. The heat receiving vapor passage 61 of the vapor passage 6 is shaped so as to extend from the heat radiating vapor passage 62 into the heat receiving portion 46 across the boundary 461 between the heat receiving portion 46 and the heat radiating portion 47. The heat receiving wick 51 is provided so as to surround the heat receiving vapor passage 61. The heat radiating vapor passage 62 includes a first passage that extends radially from the heat receiving vapor passage 61 toward the outer periphery of the housing 4, and a second vapor passage that extends radially from a position outside the heat receiving portion 46 toward the outer periphery of the housing 4.

The columnar portion 7 is provided at plural positions in a part of the heat receiving portion 46 and a part of the heat radiating portion 47. However, in the second embodiment, the entire outer periphery of the columnar portion 7 provided in the heat receiving portion 46 is in contact with the heat receiving wick 51 and does not face the heat receiving vapor passage 61. Therefore, the heat receiving wick 51 is provided so as to surround the periphery of the columnar portion 7 provided in the heat receiving portion 46 and the periphery of the heat receiving vapor passage 61.

According to the second embodiment, the heat receiving wick 51 is provided so as to surround the heat receiving vapor passage 61. Therefore, the working fluid evaporated in the heat receiving wick 51 easily flows into the vapor passage 6, and the flow velocity of the working fluid is further kept high. Therefore, the heat transport device 3 can further improve the vapor diffusion function.

### Third Embodiment

A third embodiment will be described. In the third embodiment, the configuration of the columnar portion 7 included in the heat transport device 3 is changed from that of the second embodiment, and the other configurations are the same as those of the second embodiment. Therefore, only portions different from those of the second embodiment will be described.

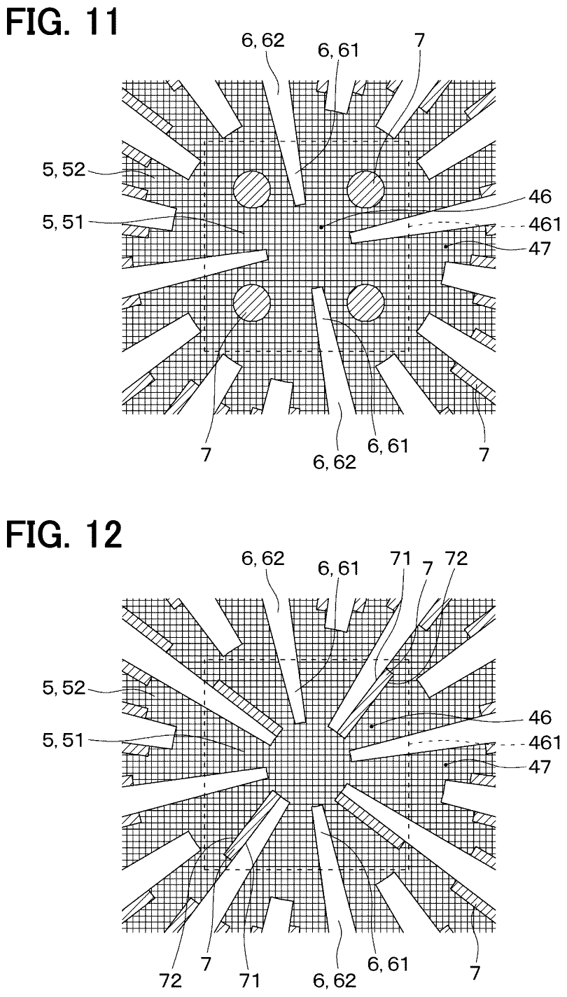

As shown in FIG. 11, in the third embodiment, the columnar portion 7 provided in the heat receiving portion 46 does not face the heat receiving vapor passage 61, and the entire outer periphery of the columnar portion 7 is in contact with the heat receiving wick 51. Therefore, the heat receiving wick 51 is provided so as to surround the periphery of the columnar portion 7 provided in the heat receiving portion 46 and the periphery of the heat receiving vapor passage 61.

Further, in the third embodiment, the columnar portion 7 provided in the heat receiving portion 46 has a circular shape in a cross-sectional view perpendicular to the thickness direction of the housing 4. Accordingly, it is possible to reduce the contact area between the outer periphery of the columnar portion 7 and the heat receiving wick 51 while securing the cross-sectional area of the columnar portion 7 perpendicular to the thickness direction of the housing 4. Specifically, the columnar portion 7 of the third embodiment can reduce the contact area between the outer periphery of the columnar portion 7 and the heat receiving wick 51 while having the same cross-sectional area as that of the columnar portion 7 having a substantially rectangular shape in a cross-sectional view perpendicular to the thickness direction of the housing 4 as described in the first and second embodiments. The contact area between the outer periphery of the columnar portion 7 and the heat receiving wick 51 is an area represented by the product of “the length in the circumferential direction of the circular shape in a cross-sectional view of the columnar portion 7” and “the height of the columnar portion 7”.

By securing the cross-sectional area of the columnar portion 7 perpendicular to the thickness direction of the housing 4, the heat resistance of the heat transport device 3 can be improved. In addition, by reducing the contact area between the outer periphery of the columnar portion 7 and the wick 5, even in case where the columnar portion 7 expands in a direction perpendicular to the thickness direction of the housing 4 from the original shape at the time of manufacturing the heat transport device 3, a region in which the wick 5 is deformed can be reduced. Therefore, a decrease in the capillary force of the wick 5 is suppressed, and the flow function of the working fluid can be improved. In the present specification, the circular shape is not limited to a perfect circle, and includes a shape deformed during manufacturing, a manufacturing tolerance, and the like.

### Modification of Third Embodiment

In the third embodiment, the columnar portion 7 provided in the heat receiving portion 46 has a circular shape in a cross-sectional view perpendicular to the thickness direction of the housing 4. In contrast, in a modification of the third embodiment, the columnar portion 7 provided in the heat receiving portion 46 may have an elliptical shape in a cross-sectional view perpendicular to the thickness direction of the housing 4. Even in this case, it is possible to reduce the contact area between the outer periphery of the columnar portion 7 and the heat receiving wick 51 while maintaining the same cross-sectional area as that of the columnar portion 7 described in the first and second embodiments. In the present specification, the elliptical shape is not limited to a mathematical ellipse (that is, a curve formed from a set of points at which the sum of distances from certain two fixed points on a plane is constant), and includes a shape deformed during manufacturing, a manufacturing tolerance, and the like.

### Fourth Embodiment

A fourth embodiment will be described. The fourth embodiment is a combination of the configuration of the first embodiment and the configuration of the second embodiment.

As shown in FIG. 12, in the fourth embodiment, plural vapor passages 6 are provided to extend over a part of the heat receiving portion 46 and a part of the heat radiating portion 47. The columnar portion 7 is provided at plural positions in a part of the heat receiving portion 46 and a part of the heat radiating portion 47. The first side 71 of the outer periphery of the columnar portion 7 faces the vapor passage 6 without being in contact with the wick 5.

At least one of the heat receiving vapor passages 61 adjacent to the columnar portion 7 faces the first side 71 of the outer periphery of the columnar portion 7. At least one of the heat receiving vapor passages 61 located away from the columnar portion 7 is surrounded by the heat receiving wick 51.

According to the fourth embodiment, the effects of both the first embodiment and the second embodiment can be achieved.

### Other Embodiments

(1) In each of the embodiments, the first side 71 of the columnar portion 7 faces the vapor passage 6, but the present disclosure is not limited thereto. For example, the entire outer periphery of the columnar portion 7 may face the vapor passage 6 (in other words, the columnar portion 7 may be disposed in the vapor passage 6).

(2) In each of the embodiments, the heat transport device 3 includes the columnar portion 7, but the present disclosure is not limited thereto. For example, the columnar portion 7 may be eliminated.

(3) In each of the embodiments, the heat transport device 3 includes the partition wall 53, but the present disclosure is not limited thereto. For example, the partition wall 53 may be eliminated.

(4) In each of the embodiments, the semiconductor element 2 is provided as a heating element in the heating element disposing portion 44 of the heat transport device 3. However, the present disclosure is not limited thereto, and the heat transport device 3 may be provided with a heating element other than the semiconductor element 2.

The present disclosure is not limited to the above embodiments, and can be appropriately modified within the scope described in the claims. The above-described embodiments and a part thereof are not irrelevant to each other, and can be appropriately combined with each other unless the combination is obviously impossible. Individual elements or features of a particular embodiment are not necessarily essential unless it is specifically stated that the elements or the features are essential in the foregoing description, or unless the elements or the features are obviously essential in principle. Further, in each of the embodiments described above, when numerical values such as the number, numerical value, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number. The shape, the positional relationship, and the like of a component or the like mentioned in the above embodiments are not limited to those being mentioned unless otherwise specified, limited to specific shape, positional relationship, and the like in principle, or the like.

What is claimed is:

1. A heat transport device configured to transport heat generated by a heating element, comprising:
a housing having a sealed space in which a working fluid is sealed;
a wick forming a capillary passage through which a liquid-phase working fluid flows inside the housing; and
a vapor passage communicating with the wick inside the housing and through which a gas-phase working fluid flows, wherein
an outer wall of the housing has a heating element disposing portion on which the heating element is disposed, and a non-disposing portion on which the heating element is not disposed,
an internal portion of the housing has a heat receiving portion positioned to correspond to the heating element disposing portion in a thickness direction of the housing, and a heat radiating portion positioned to correspond to the non-disposing portion in the thickness direction, and
both the wick and the vapor passage are provided to extend over the heat receiving portion and the heat radiating portion.

2. The heat transport device according to claim 1, further comprising a columnar portion that connects one inner wall of the housing to the other inner wall of the housing in the thickness direction, wherein the columnar portion is positioned in a part of the heat receiving portion.

3. The heat transport device according to claim 2, wherein
the housing has
an upper plate provided on one side in the thickness direction,
a lower plate provided on the other side in the thickness direction, and
an intermediate plate provided between the upper plate and the lower plate, the wick being defined in the intermediate plate, and
the columnar portion is formed by pressure-bonding a part of the upper plate, a part of the lower plate, and a part of the intermediate plate.

4. The heat transport device according to claim 2, wherein at least a part of an outer periphery of the columnar portion provided in the heat receiving portion faces the vapor passage.

5. The heat transport device according to claim 2, wherein
a part of an outer periphery of the columnar portion provided in the heat receiving portion faces the vapor passage, and
a part of an outer periphery of the columnar portion provided in the heat receiving portion that does not face the vapor passage is in contact with the wick.

6. The heat transport device according to claim 2, wherein the columnar portion provided in the heat receiving portion has a circular shape or an elliptical shape in a cross-section perpendicular to the thickness direction of the housing.

7. The heat transport device according to claim 1, wherein the wick is provided to surround a periphery of the vapor passage in the heat receiving portion.

8. A semiconductor module comprising: the heat transport device according to claim 1; and a semiconductor element corresponding to the heating element which generates heat by energization, wherein
the heat transport device transports heat generated by the semiconductor element from the heat receiving portion to the heat radiating portion.
